(19) United States
(12) Patent Application Publication
(10) Pub. No.: US 2020/0403564 A1
(43) Pub. Date: Dec. 24, 2020

(54) PRODUCTION OF A CONCENTRATING SUB-MODULE USING PHOTOVOLTAIC ASSEMBLY METHODS

(71) Applicant: COMMISSARIAT A L'ENERGIE ATOMIQUE ET AUX ENERGIES ALTERNATIVES, PARIS (FR)

(72) Inventors: Yannick ROUJOL, SAINT-CHEF (FR); Anthony BARBOT, CHAMBERY (FR); Mathieu BAUDRIT, CHAMBERY (FR); Caroline SERAINE, SAINTE-HELENE-DU-LAC (FR); Clément WEICK, GRENOBLE (FR)

(21) Appl. No.: 16/770,574

(22) PCT Filed: Nov. 30, 2018
(86) PCT No.: PCT/EP2018/083183

§ 371 Date: Jun. 5, 2020

(30) Foreign Application Priority Data
Dec. 7, 2017 (FR) 1761774

(51) Int. Cl. H02S 40/22; H01L 31/18

(52) U.S. Cl. CPC H02S 40/22; H01L 31/186

(57) ABSTRACT

A method for manufacturing a concentrating photovoltaic solar sub-module equipped with a reflective face having a concave predefined geometric shape, wherein it includes laminating, in a single step, a multi-layer assembly comprising in succession: a structural element equipped with a reflective first face and a second face, opposite the first; a photovoltaic receiver, placed on the second face of the structural element; a layer made of transparent encapsulating material, covering the photovoltaic receiver; and a transparent protective layer covering the layer made of transparent encapsulating material, the transparent protective layer and the layer made of encapsulating material covering at least the entire surface of the photovoltaic receiver; and during the lamination, the reflective face of the structural element is shaped by being brought into contact with a convex surface of a counter-mold, in order to obtain the reflective face of concave predefined geometric shape.

The invention relates to the manufacture of elements for concentrating photovoltaic modules, and more particularly for concentrating photovoltaic modules based on reflective linear parabolic concentrators (or mirrors). These elements are called concentrating photovoltaic sub-modules.

These sub-modules each comprise an optical device for concentrating light (often called a mirror or concentrator) and photovoltaic cells forming a photovoltaic receiver and placed on the back face of the mirror or concentrator, opposite the reflective face.

When they are employed, they allow a concentrating photovoltaic module to be formed, the concentrator of a sub-module having a focal line located on the back of the concentrator of a neighboring sub-module. The photovoltaic receiver of the neighboring sub-module is located level with this focal line. Thus, each mirror plays, in addition to its concentrator role, the role of carrier for a photovoltaic receiver. The concentrating photovoltaic module therefore consists in an assembly of a plurality of generally identical elements, called sub-modules.

The concentrator or mirror of these concentrating solar sub-modules possesses a reflective surface composed of a mirror, and a back face to which one or a set of photovoltaic cells is fastened (see document US 1993/5180441). The parabolic shape of the module allows the light rays to be concentrated. The light striking a first sub-module is reflected by the reflective surface, so as to concentrate the light onto the photovoltaic cell of a second sub-module located in proximity to the first module.

The reflective surface may be composed of a layer of a highly reflective metal covered with a protective film, or composed of a metal layer adhesively bonded to a substrate comprising organic composite materials (see document US 1994/5344496). A mesh of a material of high thermal conductivity may also be added to the back of the reflective surface to improve the dissipation of heat from the sub-module. The manufacture of these sub-modules is quite complex, but because it requires many steps, such as forming and polishing the reflective surface, or treating that surface. It is also necessary to provide a step of adhesively bonding the photovoltaic cells to the mirror.

It is also possible to produce a concentrating photovoltaic sub-module, of parabolic shape (see document US 2007/0256726), in which the light is not concentrated onto the focal point of a mirror, but onto the focal point of a complex solid element composed of a plurality of mirrors. In this document, the photovoltaic cells are placed on the front face of the concentrator. In order to avoid the formation of air bubbles between the various components of the sub-module, a plurality of vacuum laminations are carried out to incorporate the optics, the photovoltaic cells and the cabling. The vacuum lamination thus makes it possible to ensure a better adhesion of the optics, of the cells or of the cabling to their respective carrier using little or no adhesive. As these various lamentations form a planar composite structure, there is another manufacturing step, in which mirrors are fastened to convex or concave surfaces, in order to produce the parabolic shape, which serves to concentrate the light onto the focal point of the solid optical element.

Document US 2004/0118395 presents a parabolic solar concentrator comprising a honeycomb structure flanked by two skins. This honeycomb structure allows a lightweight concentrator, capable of supporting thin mirrors or a thin reflective surface and of good mechanical strength, to be obtained. Nevertheless, this element comprises no photovoltaic cell, because it is intended to heat a fluid. In addition, it is manufactured in a plurality of steps, in particular: the reflective surface is deformed cold, the mirrors are fastened with an adhesive to one of the skins, and the surface of the skins and of the mirrors are treated.

The invention aims to remedy the aforementioned drawbacks of the prior art; more particularly, it aims to provide a method, comprising only a single step, for manufacturing a concentrating photovoltaic sub-module.

One subject of the invention is therefore a method for manufacturing a concentrating photovoltaic solar sub-module equipped with a reflective face having a concave predefined geometric shape, characterized in that the method comprises laminating, in a single step, a multi-layer assembly comprising in succession a structural element equipped with a reflective first face and a second face, opposite the first, a photovoltaic receiver, placed on the second face of the structural element, a layer made of transparent encapsulating material, covering the photovoltaic receiver, and a transparent protective layer covering transparent encapsulant, the transparent protective layer and the layer made of encapsulating material covering at least the entire surface of the photovoltaic receiver, and characterized in that, during the lamination, the reflective face of the structural element is shaped by being brought into contact with a convex surface of a counter-mold, in order to obtain the reflective face of concave predefined geometric shape.

According to particular embodiments of the invention:
The concave predefined geometric shape of said reflective face may be parabolic;
The lamination may be a hot vacuum lamination the temperature of which is, preferably, comprised between 120° C. and 170° C.;
The encapsulating material may be made of EVA, polyolefin, silicone, thermoplastic polyurethane, polyvinyl butyral, functional polyolefin or of ionomer;
The transparent protective layer may be made of ECTFE, FEP, PMMA, PC, ETFE, PVDF, PET, of glass or of CPI;
The photovoltaic receiver may be a set of photovoltaic cells that are interconnected by wires on an IMS-PCB receiver or a set of photovoltaic cells that are interconnected by strips, the photovoltaic cells being silicon cells or multi-junction cells;
The structural element may be formed from a core flanked by two skins, one of the two skins being covered by a reflective film forming the reflective first face of the sub-module, and in this case, the skins may be made of preimpregnated polymer/fiber material, the polymer being chosen from polyester, epoxy or acrylic and the fiber being chosen from glass, carbon or aramid, and the core may be a honeycomb structure that is advantageously made of aluminum, of aramid of Nomex type, of polypropylene, or of polycarbonate, or the core may be a foam, advantageously made of PET, PU, PVC, PEI or PMI;
The reflective film may be a polymer film containing a silver or aluminum deposition; and
The structural element may comprise an aluminum mirror.

Another subject of the invention is a concentrating photovoltaic solar sub-module equipped with a reflective face having a concave predefined geometric shape, comprising a structural element equipped with a reflective first face and a second face, opposite the first face, the structural element comprising a core flanked by two skins, one of the two skins making direct contact with a reflective layer forming the reflective first face of the structural element and the reflective face of the sub-module, the second skin forming the second face of the structural element, a photovoltaic receiver, placed in direct contact with the second face of the structural element, a layer made of transparent encapsulating material, covering the photovoltaic receiver, and a transparent protective layer, forming a second face of the sub-module, which face is opposite the reflective face, covering the layer made of transparent encapsulating material.

Another subject of the invention is a concentrating photovoltaic sub-module equipped with a reflective face having a concave predefined geometric shape, comprising a structural element equipped with a reflective first face and a second face, opposite the first face, the structural element comprising an aluminum mirror forming the reflective first face of the structural element and the reflective face of the sub-module, a photovoltaic receiver, placed in direct contact with the second surface of the structural element, a layer made of transparent encapsulating material, covering the photovoltaic receiver, and a transparent protective layer, forming a second face of the sub-module, which face is opposite the reflective face, covering the layer made of transparent encapsulating material.

Other features, details and advantages of the invention will become apparent upon reading the description provided with reference to the appended drawings, which are given by way of example and which show, respectively:

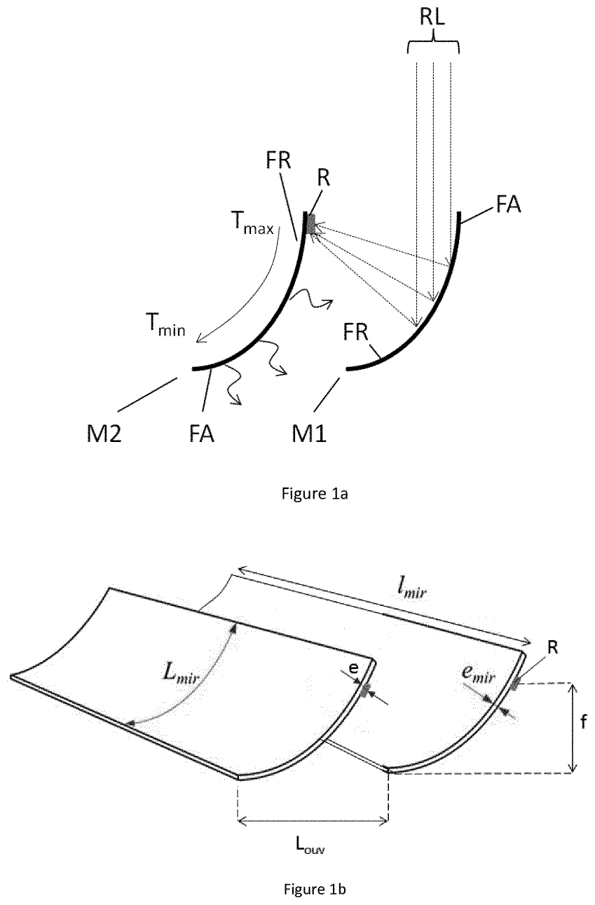

FIG. 1a, a cross section of a module composed of two sub-modules, illustrating the operation of a concentrating photovoltaic module;

FIG. 1b, the characteristic dimensions of a concentrating photovoltaic module; and

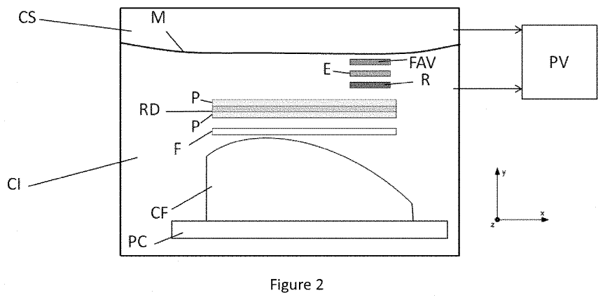

FIG. 2, an illustration of a method for manufacturing a concentrating photovoltaic sub-module according to embodiments of the invention.

The lamination is a step in which pressure is applied to two or more layers of hot material to adhesively bond and press them. The pressure and temperature of this step are dependent on the materials employed. The lamination here allows the concentrator to be shaped via application to a counter-mold.

The elements shown in the figures are not to scale, and the proportions are therefore not representative of reality.

FIG. 1a shows a cross section of two concentrating photovoltaic sub-modules, illustrating the operation of a concentrating photovoltaic module. Only two sub-modules M1 and M2 are shown, but the operation described below may applied to a multitude of sub-modules. Light rays RL strike a reflective first face FR of a first sub-module M1. The reflective face FR conventionally consists of a parabolic cylindrical mirror. The parabolic shape of the mirror of the sub-module M1 makes it possible to make the light rays RL converge on the focal point of the mirror, the position of which is precisely calculated in order for a photovoltaic receiver R to be placed there. This position also corresponds to a point on a second face FA of a second sub-module M2. The parabolic mirrors have thermal, structural and optical functions. Specifically, in addition to concentrating the light into a point, they allow heat to be dissipated, with a maximum temperature Tₘₐₓ at the receiver R and a minimum temperature Tₘᵢₙ in the lower portion of the sub-module, the receiver R being positioned in the upper portion. The dissipation of heat is represented by arrows in the figure, and the arrow linking Tₘₐₓ to Tₘᵢₙ represents the temperature gradient along the sub-module (US 1993/5180441). In order to be able to produce a system comprising a plurality of sub-modules, the second face FA of the sub-module M1 may also bear a photovoltaic receiver and the face FR of the sub-module M2 may be reflective.

FIG. 1b shows the characteristic dimensions of a concentrating photovoltaic module. The shape given to the sub-modules is a segment of parabola of focal length f. The developed width of this segment of parabola is given by Lₘᵢᵣ. The distance between two sub-modules is given by Lₒᵤᵥ. The length of the sub-modules is given by lₘᵢᵣ, the thickness of the concentrator by eₘᵢᵣ and the thickness of the sub-modules by e.

FIG. 2 shows an illustration of a method for manufacturing a concentrating photovoltaic sub-module according to one embodiment of the invention. A transparent layer FAV, covering a transparent encapsulant E, itself covering a photovoltaic receiver R, and a structural element are placed on a counter-mold CF in the lower chamber CI of a laminator, and more particularly of a laminator such as those used in the field of manufacture of planar conventional photovoltaic modules.

The structural element has a reflective face and it in particular comprises a core RD, also referred to as the reinforcement material, flanked by two skins P, one of which is covered with a reflective film F.

The transparent layer FAV and the encapsulant E cover at least the entire surface of the receiver R, the receiver R being placed between the structural element and the encapsulant E.

The structural element and the reflective film R have the same area as the desired sub-module.

The lower and upper chambers CI, CS of the laminator are pumped out by virtue of a vacuum pump PV.

The assembly made up of the transparent layer FAV, of the transparent encapsulant E, of the photovoltaic receiver R, of the skins P, of the core RD and of the reflective film F, which is denoted (FAV, E, R, P, RD, P, F), is planar and undergoes a hot lamination, preferably under vacuum, with forming achieved using the counter-mold CF.

The counter-mold CF allows the concave parabolic shape of the reflective face of the sub-module to be defined in the laminating step. It therefore has a surface intended to make direct contact with the reflective face of the structural element in the laminating step. This surface has a pre-defined geometry corresponding to the shape that it is desired to obtain for the reflective face of the structural element. The counter-mold CF may be made of metal or composite, and is covered with a nonstick layer (made of Teflon for example). The material of the counter-mold CF is chosen so as to be a thermal conductor and to have a high mechanical strength at the lamination temperature.

The temperature and pressure conditions and the length of this laminating step are selected by a person skilled in the art depending on the materials to be laminated. By way of example, the laminating step may last at least 15 minutes, the temperature of the lamination is advantageously comprised between 120° C. and 170° C. and the lamination pressure may be about 1000 mbar (10⁵ Pa).

The thickness of the assembly is preferably smaller than 10 mm in order to keep and ensure an optimal parabolic shape for the assembly. The thickness may also be limited by the useful height of the laminator and of the counter-mold CF. During the lamination, the counter-mold CF and the assembly (FAV, E, R, P, RD, P, F) for example rest on a hot plate PC and a uniform vertical load is gradually applied from above by virtue of the membrane M, which perfectly conforms to the shapes. During the lamination, it is necessary to sufficiently cross-link the encapsulant E and to correctly bake the various elements from which the module is composed, which elements are located at distances such as to be further from or closer to the hot plate PC. To this end, the hot-lamination program is optimized with respect to temperature, pressure and length depending on the materials used.

According to one embodiment of the invention, the skins P are made of preimpregnated polymer/fiber material, which allows the adhesion of the reflective film F to the core RD to be obtained. The prepreg has a thickness smaller than 200 μm and the percentage of resin is comprised between 40 and 55%. The polymer is chosen from polyester, epoxy or acrylic, whereas the fiber is chosen from glass, carbon, or aramid.

According to another embodiment of the invention, the core RD is a honeycomb structure made of aramid of Nomex type, of polypropylene, of polycarbonate or of aluminum.

According to another embodiment of the invention, the core RD is a foam made of PET (polyethylene terephthalate), PU (polyurethane), PVC (polyvinyl chloride), PEI (polyetherimide) or of PMI (polymethyneimine).

According to another embodiment of the invention, the transparent encapsulant E has a thickness smaller than 500 μm and is made of a cross-linked elastomer, such as EVA (ethyl vinyl acetate), or made of thermoplastic elastomer or made of ionically cross-linked thermoplastic copolymer (IONOMER). In the case of a thermoplastic elastomer, the encapsulant E is more particularly made of polyolefin, of silicone, of thermoplastic PU, of polyvinyl butyral or of functional polyolefin.

According to another embodiment of the invention, the transparent layer FAV has a thickness smaller than 200 μm and be made of ECTFE (or HALAR, ethylene chlorotrifluoroethylene copolymer), FEP (fluorinated ethylene propylene), PMMA (polymethyl methacrylate), PC (polycarbonate), ETFE (ethylene tetrafluoroethylene), PVDF (polyvinylidene fluoride), PET, thin glass or of CPI (transparent polyimide).

According to another embodiment of the invention, the reflective film F is a polymer film with an aluminum deposition or with a silver deposition. Ideally, the reflective film F is thick enough that the optional honeycomb core RD cannot be seen through the reflective surface of the module, in order not to disrupt the concentration of light, while ensuring that the total weight of the sub-module remains low. Advantageously, the film has a thickness comprised between 200 and 250 μm.

The choice of the materials from which the assembly (FAV, E, R, P, RD, P and F) is made depends on the weight of the targeted sub-module, on obtaining a parabolic shape, which ensures a good concentration, and on the conditions due to the environment (earth, stratosphere or space) of the module. Thus, using a carbon/epoxy prepreg, of weight per unit area comprised between 80 g/m² and 300 g/m², associated with an aluminum honeycomb of a thickness of 3 mm, it is possible to produce a stiff sub-module, of a low weight, much smaller than that of a conventional module (difference of 30%).

According to another embodiment of the invention, the photovoltaic receiver R is composed of photovoltaic cells that are interconnected by wires (wire-bonding) and mounted on an IMS-PCB (insulated metal substrate-printed circuit board) receiver by soldering or adhesive bonding using, for example, a conductive silver adhesive. The cells may also be interconnected by strips, this allowing an IMS-PCB receiver not to be used. The cells may be silicon cells or multi-junction cells made of III-V or II-VI semiconductor materials or made of a material having a perovskite structure on silicon. The cells may also be bonded to one another by soldering or by adhesive bonding, for example using a conductive silver adhesive.

The following is an example of implementation of the invention:
The transparent layer FAV is made of HALAR (ECTFE) or of FEP with a thickness of 25 μm and a weight per unit area of 54 g/m²;
The transparent encapsulant E is made of ionomer with a thickness of 50 μm and a weight per unit area of 45 g/m²;
The photovoltaic receiver R consists of triple-junction solar cells of 10 mm width and of 10 mm length and of an IMS-PCB receiver of 75 μm thickness;
The core RD is a honeycomb core made of aluminum of 3 mm thickness and of 78 g/m² weight per unit area, flanked by two skins P made of carbon/epoxy prepreg of 110 g/m² weight per unit area;
The reflective film F consists of a reflective film made of PET, of an aluminum-containing deposition and of a protective varnish, the film F having a thickness of 71 μm and a weight per unit area of 105 g/m².

The assembly is deposited on a counter-mold CF made of aluminum, having a parabolic shape of 28 mm height, in the lower chamber CI of a laminator, of 35 mm useful height. The temperature of the hot plate is 150° C. The lower chamber CI is degassed for 300 seconds: the lower and upper chambers CI, CS are pumped out by virtue of the vacuum pump PV. Next, during a second phase of 600 seconds, a uniform vertical load is gradually applied (using the membrane M) to the top of the counter-mold CF, which is placed on the hot plate PC, at a rate of 1400 mbar/min up to a plateau of 1000 mbar.

The sub-modules have a developed width Lₘᵢᵣ of 180 mm, a length lₘᵢᵣ of 1 m and a cell width of 10 mm. Their focal length f is 75 mm and the distance between two sub-modules is Lₒᵤᵥ=150 mm.

According to another subject of the invention, the structural element comprises a mirror made of aluminum having a thickness smaller than 0.5 mm. The assembly consisting of the transparent layer FAV, of the encapsulant E, of the photovoltaic receiver R and of the aluminum mirror is laminated in a single step on a counter-mold CF in the same way as above. In this case, the total weight of the sub-module is slightly greater (30%). Its mechanical strength is lower and it will therefore require additional supports: specifically three supports are necessary for a sub-module of 1 m length whereas two supports are necessary for a sub-module of the same size made of composite material. However, its lifetime is longer, because its reflective portion degrades less than organic layers.

1. A method for manufacturing a concentrating photovoltaic solar sub-module equipped with a reflective face having a concave predefined geometric shape, comprising laminating, in a single step, a multi-layer assembly comprising in succession:
a structural element provided with a reflective first face and a second face, opposite the first face;
a photovoltaic receiver, placed on the second face of the structural element;
a layer made of transparent encapsulating material, covering the photovoltaic receiver; and
a transparent protective layer covering the layer made of transparent encapsulating material; the transparent protective layer and the layer made of encapsulating material covering at least the entire surface of the photovoltaic receiver; and
during the lamination, the reflective face of the structural element is shaped by being brought into contact with a convex surface of a counter-mold, in order to obtain the reflective face of concave predefined geometric shape.

2. The method for manufacturing a concentrating photovoltaic solar sub-module as claimed in claim 1, wherein the concave predefined geometric shape of said reflective face is parabolic.

3. The method for manufacturing a concentrating photovoltaic solar sub-module as claimed in claim 1, wherein said lamination is a hot vacuum lamination, the temperature of which is, preferably, comprised between 120° C. and 170° C.

4. The method for manufacturing a concentrating photovoltaic solar sub-module as claimed in claim 1, wherein the encapsulating material is made of EVA, polyolefin, silicone, thermoplastic polyurethane, polyvinyl butyral, functional polyolefin or of ionomer.

5. The method for manufacturing a concentrating photovoltaic solar sub-module as claimed in claim 1, wherein said transparent protective layer is made of ECTFE, FEP, PMMA, PC, ETFE, PVDF, PET, of glass or of CPI.

6. The method for manufacturing a concentrating photovoltaic solar sub-module as claimed in claim 1, wherein said photovoltaic receiver is a set of photovoltaic cells that are interconnected by wires on an IMS-PCB receiver.

7. The method for manufacturing a concentrating photovoltaic solar sub-module as claimed in claim 1, wherein said photovoltaic receiver is a set of photovoltaic cells that are interconnected by strips.

8. The method for manufacturing a concentrating photovoltaic solar sub-module as claimed in claim 1, wherein said photovoltaic cells are silicon cells.

9. The method for manufacturing a concentrating photovoltaic solar sub-module as claimed in claim 1, wherein said photovoltaic cells are multi junction cells.

10. The method for manufacturing a concentrating photovoltaic solar sub-module as claimed in claim 1, wherein said structural element is formed from a core flanked by two skins, one of the two skins being covered by a reflective film forming the reflective first face of the sub-module.

11. The method for manufacturing a concentrating photovoltaic solar sub-module as claimed in claim 10, wherein said skins are made of preimpregnated polymer/fiber material, the polymer being chosen from polyester, epoxy or acrylic and the fiber being chosen from glass, carbon or aramid.

12. The method for manufacturing a concentrating photovoltaic solar sub-module as claimed in claim 10, wherein the core is a honeycomb structure that is advantageously made of aluminum, of aramid of Nomex type, of polypropylene, or of polycarbonate.

13. The method for manufacturing a concentrating photovoltaic solar sub-module as claimed in claim 10, wherein the core is a foam, advantageously made of PET, PU, PVC, PEI or PMI.

14. The method for manufacturing a concentrating photovoltaic solar sub-module as claimed in claim 10, wherein said reflective film is a polymer film containing a silver or aluminum deposition.

15. The method for manufacturing a concentrating photovoltaic solar sub-module as claimed in claim 1, wherein said structural element comprises an aluminum mirror.

16. A concentrating photovoltaic solar sub-module equipped with a reflective face having a concave predefined geometric shape, comprising:
a structural element equipped with a reflective first face and a second face, opposite the first face, the structural element comprising a core flanked by two skins, one of the two skins making direct contact with a reflective layer forming the reflective first face of the structural element and the reflective face of the sub-module, the second skin forming the second face of the structural element;
a photovoltaic receiver, placed in direct contact with the second face of the structural element;
a layer made of transparent encapsulating material, covering the photovoltaic receiver; and
a transparent protective layer, forming a second face of the sub-module, which face is opposite the reflective face, said layer covering the layer made of transparent encapsulating material.

17. A concentrating photovoltaic sub-module equipped with a reflective face having a concave predefined geometric shape, comprising:
a structural element equipped with a reflective first face and with a second face, opposite the first face, the structural element comprising an aluminum mirror forming the reflective first face of the structural element and the reflective face of the sub-module;
a photovoltaic receiver, placed in direct contact with the second surface of the structural element;
a layer made of transparent encapsulating material, covering the photovoltaic receiver; and
a transparent protective layer, forming a second face of the sub-module, which face is opposite the reflective face, said layer covering the layer made of transparent encapsulating material.
